(19) United States
(12) Patent Application Publication
(10) Pub. No.: US 2026/0246426 A1
(43) Pub. Date: Aug. 20, 2026

(54) Dual-Band Dual-Output Ports Power Amplifier Arrangements

(71) Applicant: Telefonaktiebolaget LM Ericsson (publ), Stockholm (SE)

(72) Inventors: Rui Hou, Täby (SE); Yonghai Jin, Beijing (CN); Paul Saad, Sundyberg (SE)

(21) Appl. No.: 18/872,354

(22) PCT Filed: Jun. 24, 2022
(86) PCT No.: PCT/CN2022/101104

§ 371 Date: Dec. 6, 2024

(51) Int. Cl. H03F 1/02; H03F 3/21

(52) U.S. Cl. CPC H03F 1/0288; H03F 3/211; H03F 2200/111

(57) ABSTRACT

A dual-band dual-output ports power amplifier arrangement (100) comprising a first power amplifier (Pm), a second power amplifier (Pa) and an output coupler (120). The output coupler (120) is a dual-band inverse phase coupler such that the output signal from the first power amplifier (Pm) and the output signal from the second power amplifier (Pa) with a first frequency band (F1) are combined in phase at a second port (2/Thr) of the output coupler (120) and coupled to a first output port (Out1) of the power amplifier arrangement via a first transmission line (TL1), the output signal from the first power amplifier (Pm) and the output signal from the second power amplifier (Pa) with a second frequency band (F2) are combined in phase at a third port (3/Cp) of the output coupler (120) and coupled to a second output port (Out2) of the power amplifier arrangement via a second transmission lines (TL2), the output signal from the first power amplifier (Pm) and the output signal from the second power amplifier (Pa) with the first frequency band (F1) are cancelled at the third port (3/Cp) of the output coupler (120), and the output signal from the first power amplifier (Pm) and the output signal from the second power amplifier (Pa) with the second frequency band (F2) are cancelled at the second port (2/Thr) of the output coupler (120).

### TECHNICAL FIELD

Embodiments herein relate to power amplifier arrangements. In particular, they relate to dual-band dual-output ports power amplifiers with one or more couplers, an electronic apparatus comprising one or more dual-band dual-output ports power amplifiers.

### BACKGROUND

With the rapid development of communication technologies, mobile communication systems have to accommodate many standards simultaneously. This requirement stimulates a demand for multiband power amplifiers (PA). In a conventional multiband PA solution, several single band PAs are paralleled, and outputs of each PA are added together using passive combiners or multiplexers. This multi-single-band PA architecture has a limitation that each PA power capacity is reserved only for each single band. In other words, unused power from one band cannot be shared between different frequency bands. For example, two 50W single band PAs are combined in a dual-band radio system, yielding a total 100W. However, this total power cannot be allocated all to one frequency band. The maximum output power for each frequency band is fixed with 50W. In this situation, a high efficiency multiband PA solution is highly desirable.

To support multiband requirements, a broadband high efficiency PA technology is developed recently. However, the efficiency of the broadband PA solution is still lower than a narrow band Doherty PA (DPA). That is because the bandwidth and efficiency are trade off performances in PA design. A dual-band DPA has a potential to achieve better performance than broadband DPAs, since its performance is only required within two frequency bands, but not required for the frequency bands in between these two frequency bands.

In practical radio units used for cellular base stations, the loading of a dual-band PA is often not a wideband load impedance, but two narrow-band bandpass filters. This means for dual operating bands, the PA loading is two bandpass filters. However, for a conventional dual-band or wideband PA solution, the PA has only one output port. It requires a wideband circulator and one-to-two diplexer to divide the wideband output signal from the PA to feed the two narrow-band filters. The wideband circulator, which is hard to implement, has more insertion loss than a conventional narrow band solution. Furthermore, the one-to-two diplexer causes extra insertion loss, volume, and weight.

### SUMMARY

It is therefore an object of embodiments herein to provide a high efficiency dual-band dual-output ports power amplifier.

According to one aspect of embodiments herein, the object is achieved by a dual-band dual-output ports power amplifier arrangement. The power amplifier arrangement comprises a first power amplifier having an input and an output. The input is for receiving a first signal with a first frequency band and a second signal with a second frequency band, and the output is for outputting an output signal of the first power amplifier.

The power amplifier arrangement further comprises a second power amplifier having an input and an output. The input is for receiving a third signal with a first frequency band and a fourth signal with a second frequency band and the output is for outputting an output signal of the second power amplifier.

The power amplifier arrangement further comprises an output coupler having a first port, a second port, a third port and a fourth port.

The power amplifier arrangement further comprises a first output port for providing a first output signal with the first frequency band, and a second output port for providing a second output signal with the second frequency band.

The output of the first power amplifier is coupled to the first port of the output coupler.

The output of the second power amplifier is coupled to the fourth port of the output coupler.

The second port of the output coupler is coupled to the first output port of the power amplifier arrangement via a first transmission line.

The third port of the output coupler is coupled to the second output port of the power amplifier arrangement via a second transmission line.

The output coupler is a dual-band inverse phase coupler such that the output signal from the first power amplifier and the output signal from the second power amplifier with the first frequency band are combined in phase at the second port of the output coupler and coupled to the first output port of the power amplifier arrangement; the output signal from the first power amplifier and the output signal from the second power amplifier with the second frequency band are combined in phase at the third port of the output coupler and coupled to the second output port of the power amplifier arrangement; the output signal from the first power amplifier and the output signal from the second power amplifier with the first frequency band are cancelled at the third port of the output coupler; and the output signal from the first power amplifier and the output signal from the second power amplifier with the second frequency band are cancelled at the second port of the output coupler.

In other words, the power amplifier arrangement according to embodiments herein is a high efficiency dual-band Doherty PA solution. The first amplifier is a main amplifier in the Doherty PA and the second amplifier is an auxiliary amplifier in the Doherty PA. Most Doherty PAs have a single output port. The power amplifier arrangement according to embodiments herein comprises a dual-band inverse phase coupler to achieve a dual-output ports Doherty PA for applications which need dual outputs.

Embodiments herein provide a dual-band Doherty PA with two separate output ports for the first and second frequency bands F1, F2. Embodiments herein use a dual-band coupler with inverse phase difference for the first and second frequency band signals as a power combiner for the main and auxiliary amplifiers.

Embodiments herein avoid using a wideband circulator covering both frequency bands and a diplexer to split the dual-band signal to two bandpass filters. Instead, it only requires two narrow-band circulators for the two bandpass filters and keep the PA power handling capacity sharing for two bands signal. Embodiments herein have particularly advantageous when the two bands are widely apart in frequency, for which a wideband circulator is needed and will incur large insertion loss. Furthermore, using a dual-band inverse phase coupler as an output combiner, the Doherty function can be fulfilled for dual-band applications. Embodiments herein may also be applied for unsynchronized dynamic time-division-duplex (TDD) dual-band communication system by adding switches at the output ports of the amplifier arrangement.

Therefore, embodiments herein provide a dual-band dual-output ports power amplifier with high efficiency.

### BRIEF DESCRIPTION OF THE DRAWINGS

Examples of embodiments herein are described in more detail with reference to attached drawings in which:

FIG. 1 (a) is a general structure illustrating a power amplifier arrangement according to embodiments herein, FIG. 1 (b) shows one example of generating a dual-band signal;

FIG. 2 (a)-FIG. 2 (d) are simplified basic structures of dual-band couplers;

FIG. 3 (a) and FIG. 3 (b) are simplified basic structures of a power amplifier arrangement according to embodiments herein;

FIG. 4 is a simplified basic structure of a power amplifier arrangement according to embodiments herein;

FIG. 5 is a simplified basic structure of a power amplifier arrangement according to embodiments herein;

FIG. 6 (a)-FIG. 6 (c) illustrate examples of isolation circuits;

FIG. 7 illustrates a power amplifier arrangement according to embodiments herein for TDD dual-band communication system; and

FIG. 8 is a block diagram illustrating an electronic circuit or apparatus in which the power amplifier arrangement according to embodiments herein may be implemented.

### DETAILED DESCRIPTION

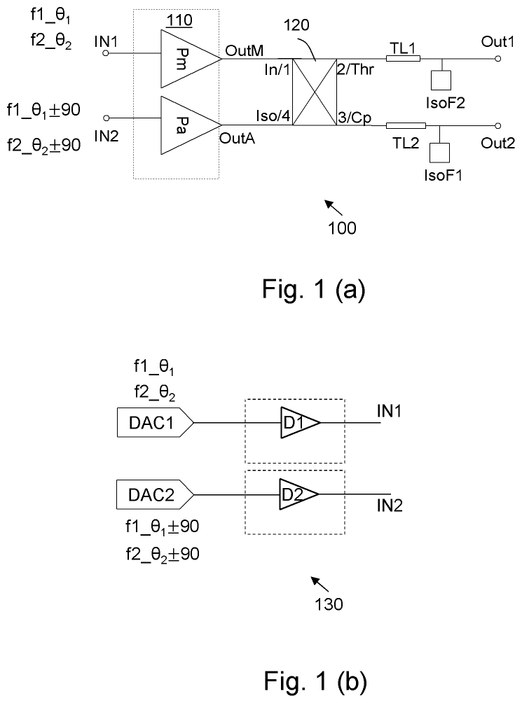

FIG. 1 (a) shows a general structure for a dual-band and dual-output ports power amplifier arrangement 100 according to embodiments herein for amplifying a dual-band input signal with a first and second frequency bands F1, F2.

The power amplifier arrangement 100 comprises a first power amplifier, i.e., a main amplifier Pm having an input IN1 and an output OutM. The input IN1 is for receiving a first signal with the first frequency band F1 with an arbitrary phase angle θ1, indicated with f1_θ₁, and a second signal with the second frequency band F2 with an arbitrary phase angle θ₂, indicated with f2_θ₂. The output is for outputting an output signal of the first power amplifier Pm.

The power amplifier arrangement 100 comprises a second power amplifier, i.e., an auxiliary amplifier Pa having an input IN2 and an output OutA. The input IN2 is for receiving a third signal with the first frequency band F1 with phase θ₁+90, indicated with f1_θ₁+90, and a fourth signal with the second frequency band F2 with phase θ₂+90, indicated with f2_θ₂+90. The output OutA is for outputting an output signal of the second power amplifier Pa.

That is the third signal should be +90 or −90 degrees phase difference with the first signal and the fourth signal should be +90 or −90 degrees phase difference with the second signal.

And the phase difference between the first signal and the third signal and the phase difference between the second signal and the fourth signal should keep the same phase difference, which means when f1_θ₁+90 is selected for the third signal, f2_θ₂+90 should be selected for the fourth signal accordingly.

The first and second amplifiers Pm, Pa form a high efficiency dual-band Doherty PA 110. The first amplifier Pm is a main amplifier in the Doherty PA 110 and the second amplifier Pa is an auxiliary amplifier in the Doherty PA 110.

The power amplifier arrangement 100 comprises an output coupler 120 having a first port, i.e., an input port In/1, a second port, i.e. a through port 2/Thr, a third port, i.e. a coupled port 3/Cp and a fourth port, i.e. an isolated port Iso/4.

The power amplifier arrangement 100 comprises a first output port Out1 for providing a first output signal with the first frequency band F1; a second output port Out2 for providing a second output signal with the second frequency band F2.

The output OutM of the first power amplifier Pm is coupled to the first port In/1 of the output coupler 120.

The output OutA of the second power amplifier Pa is coupled to the fourth port Iso/4 of the output coupler 120.

The second port 2/Thr of the output coupler 120 is coupled to the first output port Out1 of the power amplifier arrangement 100 via a first transmission line TL1.

The third port 3/Cp of the output coupler 120 is coupled to the second output port Out2 of the power amplifier arrangement 100 via a second transmission line TL2.

It can be seen that the delta phases between the first and second signals, i.e. f1_θ₁ and f2_θ₂, and the third and fourth signals, i.e. f1_θ₁+90 and f2_θ₂+90, are the same for both the main amplifier Pm, which is Δ₁=(f1_θ₁)−(f2_θ₂)=θ₁−θ₂, and for the auxiliary amplifier Pa, which is Δ₂=(f1_θ₁+90)−(f2_θ₂+90)=θ₁−θ₂, so that the envelope of the first and second signals, and the envelope of the third and fourth signals will be in phase for the main and auxiliary amplifiers Pm, Pa.

The first and second signals may be described as the dual-band input signal input to the first power amplifier, and the third and fourth signals may be described as the dual-band input signal input to the second power amplifier Pa. The dual-band input signal input to the first power amplifier Pm and the dual-band input signal input to the second power amplifier Pa shall fulfil the phase relation described above. The dual band input signals input to the first and second power amplifiers with the requested phase relation may be controlled from a digital domain. FIG. 1 (b) show one example circuit 130 for generating the dual-band input signals for inputting to the first and second power amplifiers Pm, Pa. The circuit 130 comprises a first digital-to-analog converter DAC1 and a second digital-to-analog converter DAC2 for converting digital signals to analog signals to generate the first, second, third and fourth signals with the desired phase relation. Optionally, the circuit 130 may further comprises a first driver circuit D1 connected to the input IN1 of the first amplifier Pm and a second driver circuit D2 connected to the input IN2 of the second amplifier Pa for amplifying the first, second, third and fourth signals to desired power level for inputting to the first and second power amplifiers Pm and Pa.

The output coupler 120 is a dual-band inverse phase coupler. The dual-band inverse phase coupler 120 may be implemented with different structures.

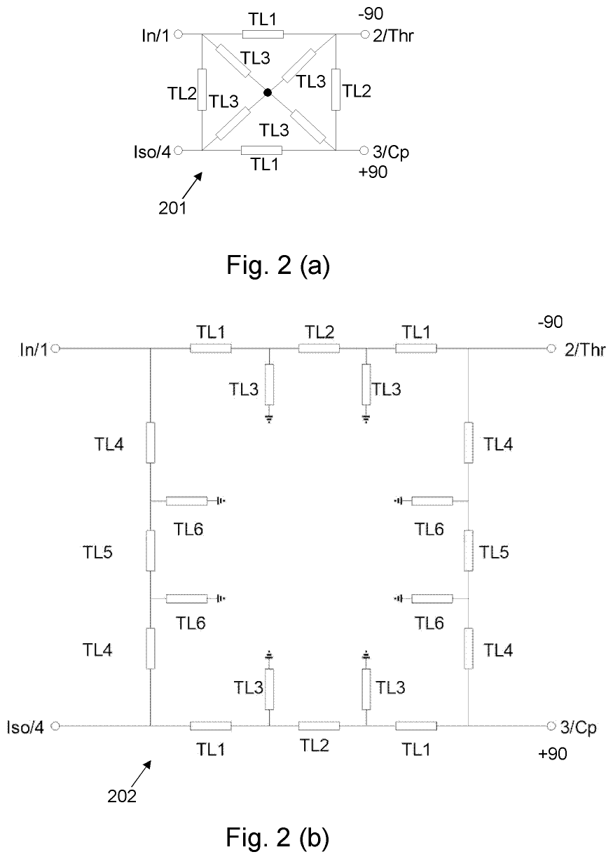

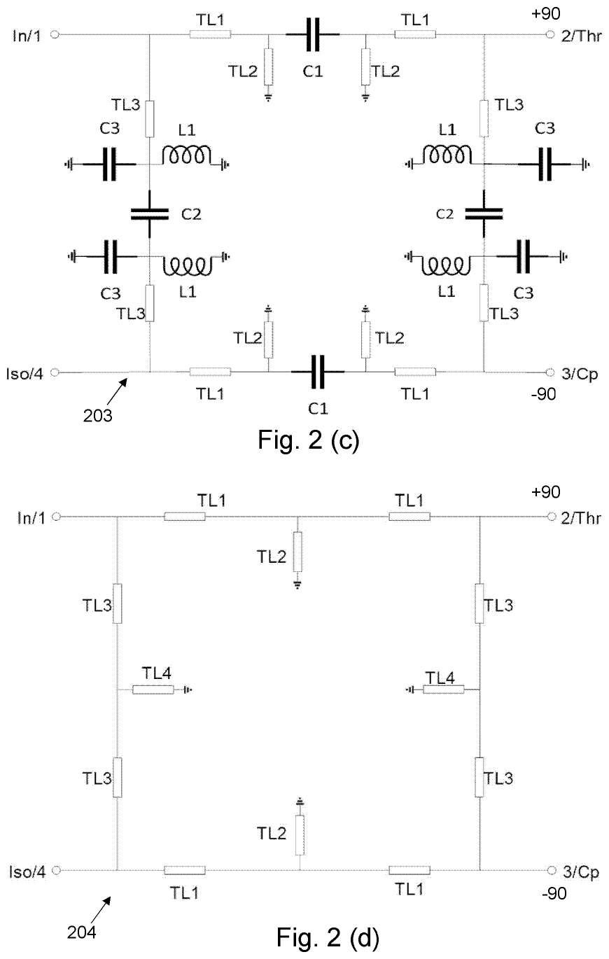

FIG. 2 (a) shows a first example structure of a dual-band inverse phase coupler 201 implemented by cross coupled transmission lines. The dual-band inverse phase coupler 201 is a 3 dB cross coupler, when a dual-band signal is applied at the first port In/1, it will be divided into two signals having the same amplitude outputting from the second port 2/Thr and the third port 3/Cp. The phase difference of these two signals will be −90 degree for the first band F1 and +90 degree for the second band F2.

FIG. 2 (b) shows a second example structure of a dual-band inverse phase coupler 202. The four ports of dual-band inverse phase coupler 202 are coupled to each other by a transmission line branch, and each transmission line branch comprises 5 transmission lines. When a dual-band signal is applied at the first port In/1, it will be divided into two signals having the same amplitude outputting from the second port 2/Thr and the third port 3/Cp. The phase difference of these two signals will be −90 degree for the first band F1 and +90 degree for the second band F2.

FIG. 2 (c) shows a third example structure of a dual-band inverse phase coupler 203. The first port In/1 and second port 2/Thr, the third port 3/Cp and fourth port Iso/4 are coupled to each other by a first type of transmission line branch comprising transmission lines and capacitor. The first port In/1 and fourth port Iso/4, the second port 2/Thr and the third port 3/Cp are coupled to each other by a second type of transmission line branch comprising transmission lines, capacitors and inductors. When a dual-band signal is applied at the first port In/1, it will be divided into two signals having the same amplitude outputting from the second port 2/Thr and the third port 3/Cp. The phase difference of these two signals will be +90 degree for the first band F1 and −90 degree for the second band F2.

FIG. 2 (d) shows a fourth example structure of a dual-band inverse phase coupler 204. The first port In/1, the second port 2/Thr, the third port 3/Cp and the fourth port Iso/4 are coupled to each other by a transmission line branch. Each transmission line branch comprises 3 transmission lines. When a dual-band signal is applied at the first port In/1, it will be divided into two signals having the same amplitude outputting from the second port 2/Thr and the third port 3/Cp. The phase difference of these two signals will be +90 degree for the first band F1 and −90 degree for the second band F2.

The dual-band inverse phase coupler 201-204 may be general defined as a dual-band coupler where the phase difference between the through port 2/Thr and coupled port 3/Cp are +/−90 degree for a signal with the first frequency band F1 and −/+90 degree for a signal with the second frequency band F2, i.e. the phase difference between the second port 2/Thr and third port 3/Cp for the first frequency band F1 is inverse to the phase difference between the second port 2/Thr and third port 3/Cp for the second frequency band F2.

The output coupler 120 may be implemented by any of the dual-band inverse phase couplers 201-204 shown in FIGS. 2 (a)-(d).

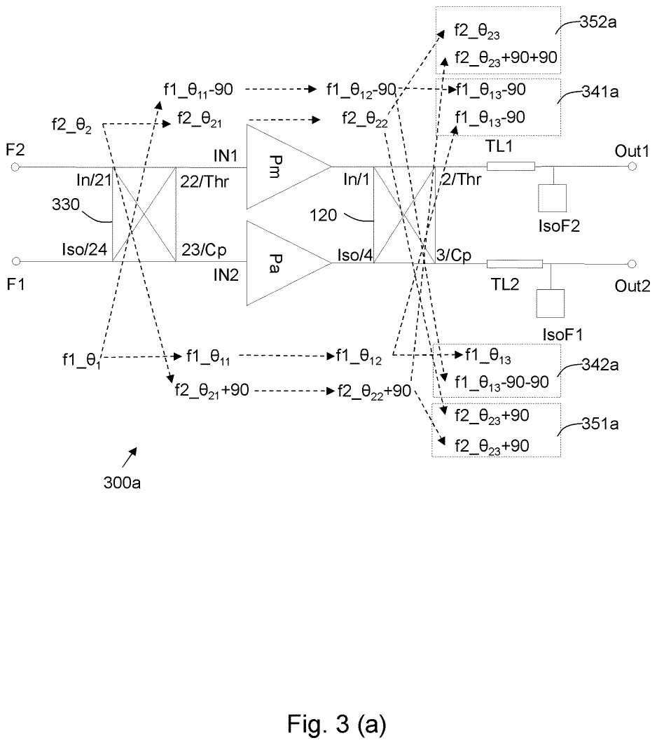

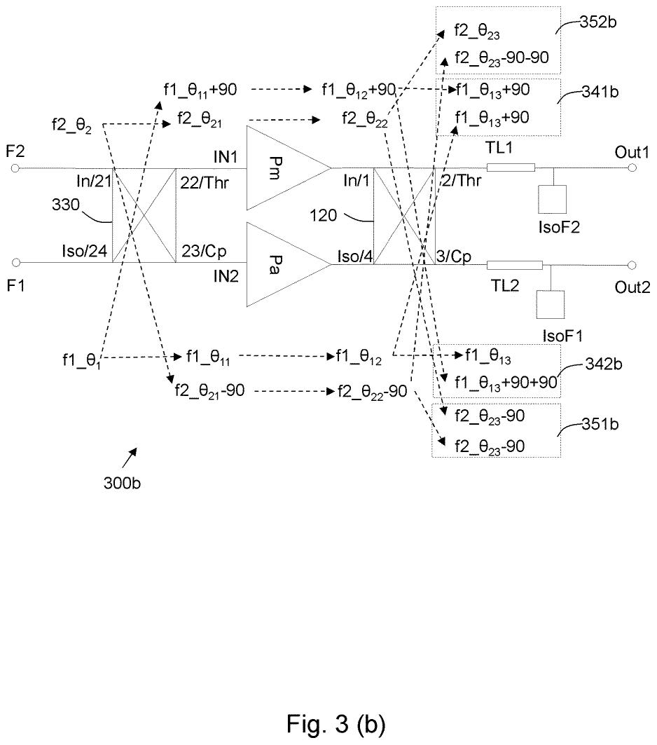

According to some embodiments herein, the power amplifier arrangement 100 may further comprise an input coupler. FIG. 3 (a) shows a dual-band power amplifier arrangement 300a with dual-input ports and dual-output ports. The power amplifier arrangement 300a has the same structure as the power amplifier arrangement 100 shown in FIG. 1 and further comprises an input coupler 330 having a first port In/21, a second port 22/Thr, a third port 23/Cp and a fourth port Iso/24.

The first port In/21 of the input coupler 330 is for receiving a second input signal with the second frequency band F2;

The fourth port Iso/24 of the input coupler 330 is for receiving a first input signal with the first frequency band F1;

The second port 22/Thr of the input coupler 330 is coupled to the input IN1 of the first power amplifier Pm; and

The third port 23/Cp of the input coupler 330 is coupled to the input IN2 of the second power amplifier Pa

The input coupler 330 and output coupler 120 may be implemented by any of the dual-band inverse phase couplers 201, 202, 203, 204 shown in FIG. 2 (a)-(d).

In the following, phase relationship between a dual-band input signal with the first and second frequency bands F1, F2 input to the dual-input ports and output from the dual-output ports of the amplifier arrangement 300a will be analysed and described.

When the input coupler 330 and output coupler 120 is implemented by the dual-band inverse phase couplers 201 or 202 shown in FIG. 2 (a) and (b), phase changes for the dual-band input signal from the input ports to output ports are indicated in FIG. 3a and will be analysed in the following. Doted arrow lines shown in FIG. 3a are to indicate the signal flows.

The dual-band input signal comprises a first input signal with the first frequency band, noted by f1_θ₁, and a second input signal with the second frequency band, noted by f2_θ₂, where θ₁ is a phase of the first input signal and θ₂ is a phase of the second input signal.

When the first input signal with the first frequency band f1_θ₁ is input to the fourth port Iso/24 of the input dual-band coupler 330, it's divided into two parts. A first part of the first input signal is output from the second port 22/Thr, noted with f1_θ₁₁−90, a second part of the first input signal is output from the third port 23/Cp, noted with f1_θ₁₁. The phase θ₁₁ may be different from θ₁, which means the phase of the signal with the first frequency band will be shift by the input dual-band coupler 330, but the phase shift delta, i.e., the phase difference between the output signals from the second port 22/Thr and third port 23/Cp is −90 degree, i.e., θ₁₁−90−θ₁₁=−90.

When the second input signal with the second frequency band f2_θ₂ is input to the first port In/21 of the input dual-band coupler 330, it's divided into two parts. A first part of the second input signal is output from the second port 22/Thr, noted with f2_θ₂₁, a second part of the second input signal is output from the third port 23/Cp, noted with f2_θ₂₁+90. Then the first part of the first input signal f1_θ₁₁−90, and the first part of the second input signal f2_θ₂₁, are input into the main amplifier Pm and then output from the main amplifier Pm, noted with f1_θ₁₂−90, f2_θ₂₂, and the second part of the first input signal f1_θ₁₁, and the second part of the second input signal f2_θ₂₁+90, are input into the auxiliary amplifier Pa and then output from the auxiliary amplifier Pa, noted with f1_θ₁₂, f2_θ₂₂+90. It can be seen that the delta phases between the signals with the first frequency band and the signals with the second frequency band are the same for both the main amplifier Pm which is Δ₁=(f1_θ₁₁−90)−(f2_θ₂₁)−θ₁₁−90−θ₂₁ and for the auxiliary amplifier Pa which is Δ₂−(f1_θ₁₁)−(f2_θ₂₁+90)=θ₁₁−θ₂₁−90, so that the envelope of the dual-band signal of f1_θ₁₁−90 and f2_θ₂₁ input to the main amplifier Pm, and the envelope of the dual-band signal of f1_θ₁₁ and f2_θ₂₁+90 input to the auxiliary amplifier Pa, will be in phase for the main and auxiliary amplifiers Pm, Pa.

The output signals, f1_θ₁₂−90 and f2_θ₂₂, f1_θ₁₂ and f2_θ₂₂+90, from the main and auxiliary amplifiers Pm, Pa, will reach to the output dual-band coupler 120 which is connected to the outputs of the main and auxiliary amplifiers Pm, Pa. The phase changing difference between the main and auxiliary amplifiers can be ignored, because it can be compensated by matching networks. The signal with the first frequency band output from the main amplifier Pm, f1_θ₁₂−90, hereafter referred as a main amplified first band signal, will input to the first port In/1 of the output dual-band coupler 120 and divides into two parts. A first part of the main amplified first band signal is output from the second port 2/Thr, noted with f1_θ₁₃−90, and a second part of the main amplified first band signal is output from the third port 3/Cp, noted with f1_θ₁₃−90−90. The signal with the first frequency band output from the auxiliary amplifier Pa, f1_θ₁₂, hereafter referred as an auxiliary amplified first band signal, will input to the fourth port Iso/4 of the output dual-band coupler 120 and divides into two parts. A first part of the auxiliary amplified first band signal is output from the second port 2/Thr, noted with f1_θ₁₃−90, and a second part of the auxiliary amplified first band signal is output from the third port 3/Cp, noted with f1_θ₁₃. The first part of the auxiliary amplified first band signal f1_θ₁₃−90 and the first part of the main amplified first band signal f1_θ₁₃−90, indicted in box 341a, are in-phase and will be combined at the second port 2/Thr of the output dual-band coupler 120. The second port 2/Thr is coupled to the first output Out1 of the amplifier arrangement 300a via the first transmission line TL1. The second part of the main amplified first band signal f1_θ₁₃−90−90 and the second part of the auxiliary amplified first band signal f1_θ₁₃, indicted in box 342a, are out-of-phase and will be cancelled at the third port 3/Cp of the output dual-band coupler 120.

In other words, the first input signal with the first frequency band f1_θ₁ input to the fourth port Iso/24 of the input dual-band coupler 330 will be in-phase and combined at the second port 2/Thr of the output dual-band coupler 120 and will be out-of-phase and cancelled at the third port 3/Cp of the output dual-band coupler 120.

Similar analysis can be applied to the second input signal with the second frequency band f2_θ₂. Continuing from the above after the main and auxiliary amplifiers, the signal with the second frequency band output from the main amplifier Pm, f2_θ₂₂, hereafter referred as a main amplified second band signal, will input to the first port In/1 of the output dual-band coupler 120 and divides into two parts. A first part of the main amplified second band signal is output from the second port 2/Thr, noted with f2_θ₂₃, and a second part of the main amplified second band signal is output from the third port 3/Cp, noted with f2_θ₂₃+90. The signal with the second frequency band output from the auxiliary amplifier Pa, f2_θ₂₂+90, hereafter referred as an auxiliary amplified second band signal, will input to the fourth port Iso/4 of the output dual-band coupler 120 and divided into two parts. A first part of the auxiliary amplified second band signal is output from the second port 2/Thr, noted with f2_θ₂₃+90+90, and a second part of the auxiliary amplified second band signal is output from the third port 3/Cp, noted with f2_θ₂₃+90. These two signals, i.e., the second part of the auxiliary amplified second band signal f2_θ₂₃+90, and the second part of the main amplified second band signal f2_θ₂₃+90, at the third port 3/Cp, indicted in box 351a, will be combined in phase at the third port 3/Cp of the output dual-band coupler 120 and coupled to the second output Out2 of the amplifier arrangement 300a via a second transmission line TL2. These two signals, i.e., the first part of the main amplified second band signal f2_θ₂₃, and the first part of the auxiliary amplified second band signal f2_θ₂₃+90+90, at the second port 2/Thr, indicted in box 352a, are out phase and cancelled at the second port 2/Thr of the output dual-band coupler 120.

That is the second input signal with the second frequency band f2_θ₂ input to the first port In/21 of the input coupler 330 will be in phase and combined at the third port 3/Cp of the output dual-band coupler 120, and will be out-of-phase and cancelled at the second port 2/Thr of the output dual-band coupler 120.

Similar analysis can be done when the input coupler 330 and output coupler 120 is implemented by the dual-band inverse phase couplers 203 or 204 shown in FIGS. 2 (c) and (d). FIG. 3 (b) shows a dual-band power amplifier arrangement 300b with dual-input ports and dual-output ports, where the phase changes and signal flows are indicated with dotted arrow lines when the input coupler 330 and output coupler 120 are implemented by the dual-band inverse phase couplers 203 or 204 shown in FIGS. 2 (c) and (d).

When the first input signal with the first frequency band f1_θ₁ is input to the fourth port Iso/24 of the input dual-band coupler 330, it's divided to two parts. A first part of the first input signal is output from the second port 22/Thr, noted with f1_θ₁₁+90, a second part of the first input signal is output from the third port 23/Cp, noted with f1_θ₁₁. The phase θ₁₁ may be different from θ₁, which means the phase of the signal with the first frequency band will be shift by the input dual-band coupler 330, but the phase shift delta, i.e., the phase difference between the output signals from the second port 22/Thr and third port 23/Cp is +90 degree, i.e., θ₁₁+90−θ₁₁=+90.

When the second input signal with the second frequency band f2_θ₂ is input to the first port In/21 of the input dual-band coupler 330, it's divided to two parts. A first part of the second input signal is output from the second port 22/Thr, noted with f2_θ₂₁, a second part of the second input signal is output from the third port 23/Cp, noted with f2_θ₂₁−90. Then the first part of the first input signal f1_θ₁₁+90, and the first part of the second input signal f2_θ₂₁, are input into the main amplifier Pm and then output from the main amplifier Pm, noted with f1_θ₁₂₊₉₀, f2_θ₂₂, and the second part of the first input signal f1_θ₁₁, and the second part of the second input signal f2_θ₂₁−90, are input into the auxiliary amplifier Pa and then output from the auxiliary amplifier Pa, noted with f1_θ₁₂, f2_θ₂₂−90. It can be seen that the delta phases between the signals with the first frequency band and the signals with the second frequency band are the same for both the main amplifier Pm which is Δ₁−(f1_θ₁₁+90)−(f2_θ₂₁)=θ₁₁+90−θ₂₁ and for the auxiliary amplifier Pa which is 42=(f1_θ₁₁)−(f2_θ₂₁−90)=θ₁₁−θ₂₁+90, so that the envelope of the dual-band signal of f1_θ₁₁+90 and f2_θ₂₁ input to the main amplifier Pm, and the envelope of the dual-band signal of f1_θ₁₁ and f2_θ₂₁−90 input to the auxiliary amplifier Pa, will be in phase for the main and auxiliary amplifiers Pm, Pa.

The output signals, f1_θ₁₂+90 and f2_θ₂₂, f1_θ₁₂ and f2_θ₂₂−90, from the main and auxiliary amplifiers Pm, Pa, will reach to the output dual-band coupler 120 which is connected at the outputs of the main and auxiliary amplifiers Pm, Pa. The phase changing difference between the main and auxiliary amplifiers can be ignored, because it can be compensated by matching networks. The signal with the first frequency band output from the main amplifier Pm, f1_θ₁₂+90, hereafter referred as a main amplified first band signal, will input to the first port In/1 of the output dual-band coupler 120 and divided to two parts. A first part of the main amplified first band signal is output from the second port 2/Thr, noted with f1_θ₁₃+90, and a second part of the main amplified first band signal is output from the third port 3/Cp, noted with f1_θ₁₃+90+90. The signal with the first frequency band output from the auxiliary amplifier Pa, f1_θ₁₂, hereafter referred as an auxiliary amplified first band signal, will input to the fourth port Iso/4 of the output dual-band coupler 120 and divided into two parts. A first part of the auxiliary amplified first band signal is output from the second port 2/Thr, noted with f1_θ₁₃+90, and a second part of the auxiliary amplified first band signal is output from the third port 3/Cp, noted with f1_θ₁₃. These two signals, i.e., the first part of the auxiliary amplified first band signal f1_θ₁₃+90 and the first part of the main amplified first band signal f1_θ₁₃+90, at the second port 2/Thr indicted in box 341b, are in-phase and will be combined at the second port 2/Thr of the output dual-band coupler 120 and coupled to the first output Out1 of the amplifier arrangement 300b via a first transmission line TL1. These two signals, i.e., the second part of the main amplified first band signal f1_θ₁₃+90+90 and the second part of the auxiliary amplified first band signal f1_θ₁₃, indicted in box 342b at the third port 3/Cp of the output dual-band coupler 120, are out-of-phase and will be cancelled at the third port 3/Cp of the output dual-band coupler 120.

Similar analysis can be applied to the second input signal with the second frequency band f2_θ₂. Continuing from the above analysis after the main and auxiliary amplifiers, the signal with the second frequency band output from the main amplifier Pm, f2_θ₂₂, hereafter referred as a main amplified second band signal, will input to the first port In/1 of the output dual-band coupler 120 and divided to two parts. A first part of the main amplified second band signal is output from the second port 2/Thr, noted with f2_θ₂₃, and a second part of the main amplified second band signal is output from the third port 3/Cp, noted with f2_θ₂₃−90. The signal with the second frequency band output from the auxiliary amplifier Pa, f2_θ₂₂−90, hereafter referred as an auxiliary amplified second band signal, will input to the fourth port Iso/4 of the output dual-band coupler 120 and divided into two parts. A first part of the auxiliary amplified second band signal is output from the second port 2/Thr, noted with f2_θ₂₃−90−90, and a second part of the auxiliary amplified second band signal is output from the third port 3/Cp, noted with f2_θ₂₃−90. These two signals, i.e., the second part of the auxiliary amplified second band signal f2_θ₂₃−90, and the second part of the main amplified second band signal f2_θ₂₃−90, at the third port 3/Cp, indicted in box 351b, will be combined in phase at the third port 3/Cp of the output dual-band coupler 120 and coupled to the second output Out2 of the amplifier arrangement 300b via a second transmission line TL2. These two signals, i.e., the first part of the main amplified second band signal f2_θ₂₃, and the first part of the auxiliary amplified second band signal f2_θ₂₃−90−90, at the second port 2/Thr, indicted in box 352b, are out phase and cancelled at the second port 2/Thr of the output dual-band coupler 120.

That is the first input signal with the first frequency band f1_θ₁ input to the fourth port Iso/24 of the input dual-band coupler 330 will be in-phase and combined at the second port 2/Thr of the output dual-band coupler 120 and will be out-of-phase and cancelled at the third port 3/Cp of the output dual-band coupler 120. The second input signal with the second frequency band f2_θ₂ input to the first port In/21 of the input coupler 330 will be in phase and combined at the third port 3/Cp of the output dual-band coupler 120 and will be out-of-phase and cancelled at the second port 2/Thr of the output dual-band coupler 120.

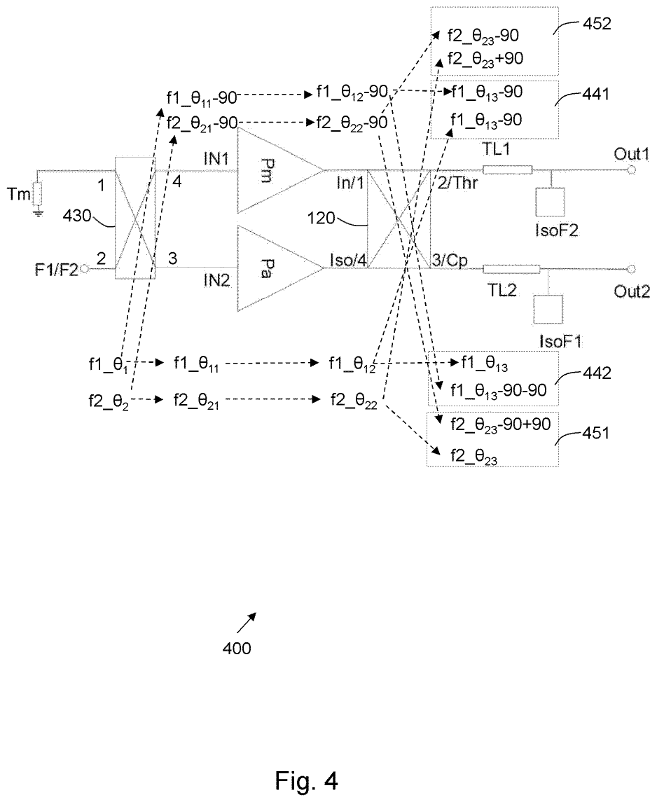

According to some embodiments herein, the power amplifier arrangement 100 may further comprise an input wideband hybrid coupler. FIG. 4 shows a dual-band power amplifier arrangement 400 with single input and dual-output ports. The power amplifier arrangement 400 has the same structure as the power amplifier arrangement 100 shown in FIG. 1 and further comprises an input wideband hybrid coupler 430 having a first port 1, a second port 2, a third port 3 and a fourth port 4.

The first port 1 of the input wideband hybrid coupler 430 is coupled to a signal ground via an impedance Tm.

The second port 2 of the input wideband hybrid coupler 430 is for receiving a dual-band input signal i.e., a first input signal with the first frequency band F1 and a second input signal with the second frequency band F2.

The third port 3 of the input wideband hybrid coupler 430 is coupled to the input IN2 of the second power amplifier Pa.

The fourth port 4 of the input wideband hybrid coupler 430 is coupled to the input IN1 of the first power amplifier Pm.

The input wideband hybrid coupler 430 is a 3 dB 90° hybrid coupler and its S parameter matrix is described by:

$$[ S ] = [ \begin{matrix}\begin{matrix}0 & 0 \\ 0 & 0\end{matrix} & \begin{matrix}- j \frac{\sqrt{2}}{2} & \frac{\sqrt{2}}{2} \\ \frac{\sqrt{2}}{2} & - j \frac{\sqrt{2}}{2}\end{matrix} \\ \begin{matrix}- j \frac{\sqrt{2}}{2} & \frac{\sqrt{2}}{2} \\ \frac{\sqrt{2}}{2} & - j \frac{\sqrt{2}}{2}\end{matrix} & \begin{matrix}0 & 0 \\ 0 & 0\end{matrix}\end{matrix} ]$$

The input wideband hybrid coupler 430 is used as a wideband input power divider. When the dual-band input signal is input from the second port 2, it will be divided to two signals with the same power level and come out from the third port 3 and the fourth port 4 with 90 degrees phase differential for both the first and second bands signals. The phase changes and signal flows are indicated in FIG. 4, when the output coupler 120 is implemented by the dual-band inverse phase couplers 201 or 202 shown in FIGS. 2 (a) and (b). Similar analysis as for FIG. 3a can be done for FIG. 4.

As can be seen, the first input signal with the first frequency band f1_θ₁ input to the second port 2 of the input coupler 430, is divided by the input coupler 430 to two parts, f1_θ₁₁ and f1_θ₁₁−90, the two parts are amplified by the main and auxiliary amplifiers and then input to the output dual-band coupler 120. The amplified two parts of the first input signal with the first frequency band output from the output dual-band coupler 120 will be in phase and combined at the second port 2/Thr of the output dual-band coupler 120, f1_θ₁₃−90, f1_θ₁₃−90, indicated in box 441, and will be out-of-phase and cancelled at the third port 3/Cp of the output dual-band coupler 120, f1_θ₁₃, f1_θ₁₃−90−90, indicated in box 442. The second input signal with the second frequency band f2_θ₂ input to the second port 2 of the input coupler 430, is divided by the input coupler 430 to two parts, f2_θ₂₁ and f2_θ₂₁−90, the two parts are amplified by the main and auxiliary amplifiers and then input to the output dual-band coupler 120. The amplified two parts of the second input signal with the second frequency band output from the output dual-band coupler 120, will be in phase and combined at the third port 3/Cp of the output dual-band coupler 120, f2_θ₂₃−90+90, f2_θ₂₃ indicated in box 451, and will be out-of-phase and cancelled at the second port 2/Thr of the output dual-band coupler 120, f2_θ₂₃−90, f2_θ₂₃+90 indicated in box 452.

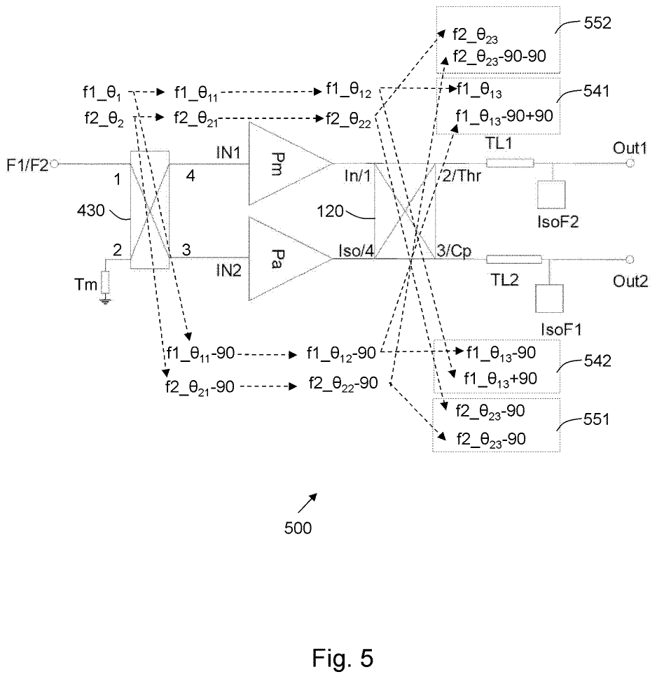

According to some embodiments herein, the dual-band input signal may be input from the first port 1 of the input wideband hybrid coupler 430. FIG. 5 shows a dual-band power amplifier arrangement 500 with single input and dual-output ports. The power amplifier arrangement 500 has the same structure as the power amplifier arrangement 400 shown in FIG. 4, where the dual-band input signal is input from the first port 1 of the input wideband hybrid coupler 430, and the second port 2 of the input wideband hybrid coupler 430 is coupled to a signal ground via an impedance Tm.

The phase changes and signal flows are indicated in FIG. 5, when the output coupler 120 is implemented by the dual-band inverse phase couplers 203 or 204 shown in FIGS. 2 (c) and (d). Similar analysis as for FIG. 3a can be done for FIG. 5.

As can be seen, the first input signal with the first frequency band f1_θ₁ input to the first port 1 of the input coupler 430, is divided by the input coupler 430 to two parts, f1_θ₁₁ and f1_θ₁₁−90, the two parts are amplified by the main and auxiliary amplifiers and then input to the output dual-band coupler 120. The amplified two parts of the first input signal with the first frequency band output from the output dual-band coupler 120, will be in phase and combined at the second port 2/Thr of the output dual-band coupler 120, f1_θ₁₃, f1_θ₁₃−90+90, indicated in box 541, and will be out-of-phase and cancelled at the third port 3/Cp of the output dual-band coupler 120, f1_θ₁₃−90, f1_θ₁₃+90, indicated in box 542. The second input signal with the second frequency band f2_θ₂ input to the first port 1 of the input coupler 430, is divided by the input coupler 430 to two parts, the two parts are amplified by the main and auxiliary amplifiers and then input to the output dual-band coupler 120. The amplified two parts of the second input signal with the second frequency band output from the output dual-band coupler 120, will be in phase and combined at the third port 3/Cp of the output dual-band coupler 120, f2_θ₂₃−90, f2_θ₂₃−90 indicated in box 551, and will be out-of-phase and cancelled at the second port 2/Thr of the output dual-band coupler 120, f2_θ₂₃, f2_θ₂₃−90−90, indicated in box 552.

The dual-band power amplifier arrangement 400, 500 shown in FIGS. 4 and 5 achieve a single input port and dual-output ports, dual-band Doherty PA.

With the phase relationship analysed above in mind, it can be summarized that:

The output signal from the first power amplifier Pm and the output signal from the second power amplifier Pa with the first frequency band F1 are combined in phase at the second port 2/Thr of the output coupler 120 and coupled to the first output port Out1 of the power amplifier arrangement via the first transmission line TL1.

The output signal from the first power amplifier Pm and the output signal from the second power amplifier Pa with the second frequency band F2 are combined in phase at the third port 3/Cp of the output coupler 120 and coupled to the second output port Out2 of the power amplifier arrangement via the second transmission lines TL2.

The output signal from the first power amplifier Pm and the output signal from the second power amplifier Pa with the first frequency band F1 are cancelled at the third port 3/Cp of the output coupler 120.

The output signal from the first power amplifier Pm and the output signal from the second power amplifier Pa with the second frequency band F2 are cancelled at the second port 2/Thr of the output coupler 120.

Embodiments herein may be applied for a Doherty PA, wherein the first amplifier Pm is the main amplifier of the Doherty PA, and the second amplifier Pa is the auxiliary amplifier of the Doherty PA. When the main amplifier Pm is biased in Class B operation mode and the auxiliary amplifier Pa is biased in Class C operation mode, an offset line TL1 and a band isolation circuit, noted with IsoF2, may be inserted at the second port 2/Thr of the output coupler 120, meanwhile an offset line TL2 and a band isolation circuit, noted with IsoF1, may be inserted at the third port 3/Cp of the output coupler 120, as shown in FIGS. 1, 3, 4, and 5. The band isolation circuit IsoF2 inserted at the second port 2/Thr of the output coupler 120 is to isolate the signal with the second frequency band, and the band isolation circuit IsoF1 inserted at the third port 3/Cp of the output coupler 120 is to isolate the signal with the first frequency band. Tuning the electrical length of the offset lines TL1, TL2, the main amplifier Pm can get the right load modulation impedance, for example 2 times of an optimum load impedance, 2*Zopt, to achieve maximum efficiency, for both frequency bands signals in small signal power level when the auxiliary amplifier Pa is turned off.

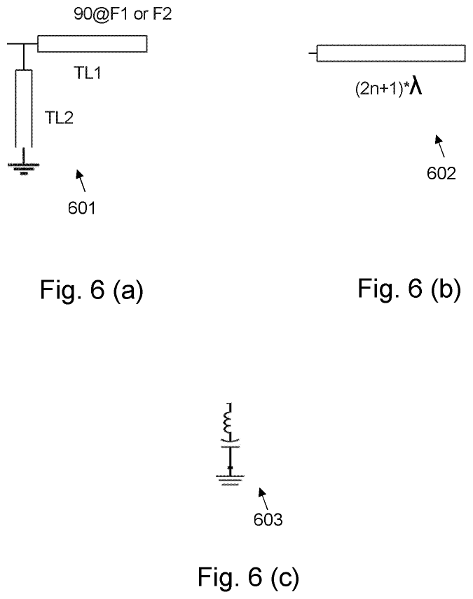

The isolation circuits IsoF1, IsoF2 can filter out unwanted signal or short the unwanted signal to ground from the outputs of the power amplifier arrangement 100, 300, 400, 500. The isolation circuit IsoF1, IsoF2 may be a parallel resonator 601 comprising two transmission lines TL1, TL2 as shown in FIG. 6(a), or a (2n+1)*λ Quarter wavelength open transmission line 602, n=0, 1, 2, . . . as shown in FIG. 6(b), or a series Inductor-Capacitor (LC) resonance circuit 603, as shown in FIG. 6(c).

The isolation circuit 601, 602, 603 may be configured to resonance at a certain frequency to filter out the signal with this frequency from the output of the power amplifier arrangement 100, 300, 400, 500. The isolation circuit 601, 602, 603 is short to ground for the signal at the resonance frequency of the isolation circuit, so it can isolate the leakage signal which should go out to another output port.

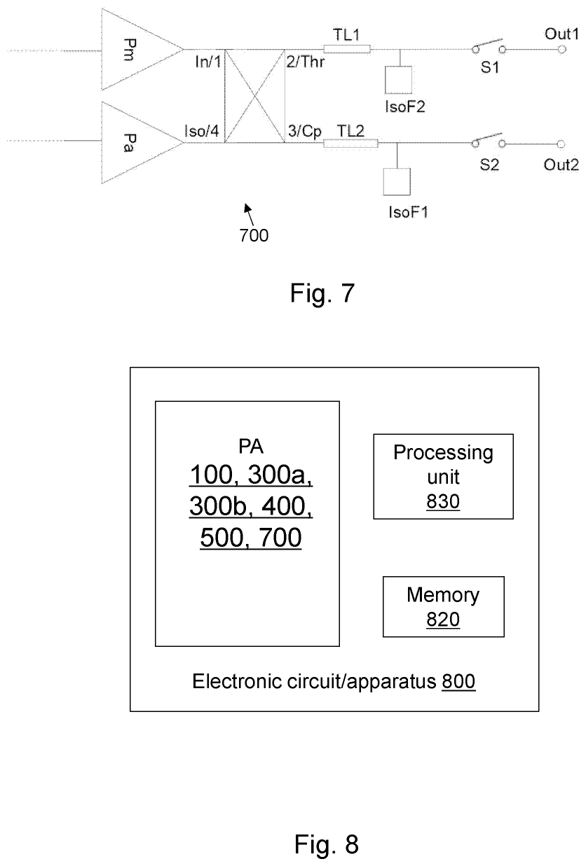

Embodiments herein may be applied in unsynchronized dynamic time-division-duplex (TDD) communication system. FIG. 7 shows a dual-band dual-output ports amplifier arrangement 700 for an unsynchronized dynamic TDD communication system. The amplifier arrangement 700 has the same structure as the amplifier arrangement 100, 300, 400, 500 and further comprises a first switch S1 at the first output port Out1 and a second switch S2 at the second output port Out2. The first switch S1 is coupled in series with the first output port Out1 and the second switch S2 is coupled in series with the second output port Out2.

During dynamic unsynchronized TDD operation, for each frequency band, a transmitting band signal will leak to a receiving band as noise. By adding the switches at each output port, this can be avoided. When the first frequency band F1 works in transmitting mode and the second frequency band F2 works in receiving mode, the first switch S1 is turned on, and the second switch S2 is turned off. When the first frequency band F1 works in receiving mode and the second frequency band F2 works in transmitting mode, the first switch S1 is turned off, and the second switch S2 is turned on.

The power amplifier arrangement 100, 300a, 300b, 400, 500, 700 according to embodiments herein may be employed in various electronic circuits or apparatus. FIG. 8 shows a block diagram for an electronic circuit or apparatus 800. The electronic circuit or apparatus 800 comprises a power amplifier arrangement PA 100, 300a, 300b, 400, 500, 700, according to the embodiments herein. The electronic circuit or apparatus 800 may be a transmitter or a transceiver in a cellular communications system/network. The electronic apparatus 800 may comprise other units, where a memory 820, a processing unit 830 are shown. The electronic apparatus 800 may also be a user equipment or a mobile device, a wireless communication device, a radio base station, or a network node for a cellular communication system.

According to some embodiments herein, a multiband power amplifier may be realized by using two or more dual-band dual-output ports power amplifier arrangements 100, 300a, 300b, 400, 500, 700 according to embodiments herein in parallel.

To summarize, embodiments herein provide a dual-band Doherty PA with two separate output ports for the first and second frequency bands F1, F2. Embodiments herein use a dual-band coupler with inverse phase difference for the first and second frequency band signals as a power combiner for the main and auxiliary amplifiers Pm, Pa. So when a signal with the first frequency band F1 is input into the first port of this coupler, it will come out from the second port and third port with a phase difference +90 degree, e.g. 0 degree at the second port and −90 degree at the third port, i.e. 0−(−90)−+90, and when a signal with the second frequency band F2 is input into the first port of this coupler, it will come out from the second port and third port with phase difference −90 degree, e.g. 0 degree at the second port and +90 degree at the third port, 0−(+90)=−90. So the phase difference between the second port and third port for the first frequency band F1 is inverse to the phase difference between the second port and third port for the second frequency band F2. With this inverse phase coupler, an envelope signal of a dual-band signal can be input in phase for the main and auxiliary amplifiers Pm, Pa as the phase difference for the first and second frequency bands is the same. For examples, the first frequency band signal may be set to-90 degree and the second frequency band signal may be set to 0 degree for the main amplifier Pm and the first frequency band signal may be set to 0 degree and the second frequency band signal may be set to +90 degree for the auxiliary amplifier Pa. In this way, the envelop signal of the dual-band signal works in phase for the main and auxiliary amplifiers Pm, Pa. The amplified signals from the main and auxiliary amplifiers Pm, Pa at the first frequency band F1 output from the second port of the dual-band inverse phase coupler 120 will be in phase and combined at the first output port of the amplifier arrangement 100, 300a, 300b, 400, 500, 700 and the amplified signals from the main and auxiliary amplifiers Pm, Pa at the first frequency band F1 output from the third port of the dual-band inverse phase coupler 120 will be out-of-phase and cancelled at the second output port of the amplifier arrangement 100, 300a, 300b, 400, 500, 700. The amplified signals from the main and auxiliary amplifiers Pm, Pa at the second frequency band F2 output from the third port 3/Cp of the dual-band inverse phase coupler 120 will be in phase and combined at the second output port of the amplifier arrangement 100, 300a, 300b, 400, 500, 700 and the amplified signals from the main and auxiliary amplifiers Pm, Pa at the second frequency band F2 output from the second port 2/Thr of the dual-band inverse phase coupler 120 will be out-of-phase and cancelled at the first output port of the amplifier arrangement 100, 300a, 300b, 400, 500, 700.

Embodiments herein avoid using a wideband circulator covering both frequency bands and a diplexer to split the dual-band signal to two bandpass filters. Instead, it only requires two narrow-band circulators for the two bandpass filters and keep the PA power handling capacity sharing for two bands signal. Embodiments herein are particularly advantageous when the two bands are widely apart in frequency, for which a wideband circulator is needed and will incur large insertion loss. Furthermore, using a dual-band inverse phase coupler as an output combiner, the Doherty function can be fulfilled for dual-band applications. Embodiments herein may also be applied for unsynchronized dynamic TDD dual-band communication system by adding switches at the output ports of the amplifier arrangement 100, 300a, 300b, 400, 500, 700.

Those skilled in the art will understand that the power amplifier arrangement 100, 300a, 300b, 400, 500, 700 according to embodiments herein may be implemented by any semiconductor technology.

When using the word “comprise” or “comprising” it shall be interpreted as non-limiting, i.e., meaning “consist at least of”.

The embodiments herein are not limited to the above described embodiments. Various alternatives, modifications and equivalents may be used. Therefore, the above embodiments should not be taken as limiting the scope of the embodiments herein, which is defined by the appended claims.

1.-9. (canceled)

10. A dual-band dual-output ports power amplifier arrangement comprising:
a first power amplifier having an input and an output, the input being for receiving a first signal with a first frequency band and a second signal with a second frequency band, and the output being for outputting an output signal of the first power amplifier;
a second power amplifier having an input and an output, the input being for receiving a third signal with the first frequency band and a fourth signal with the second frequency band, and the output being for outputting an output signal of the second power amplifier;
an output coupler having a first port, a second port, a third port and a fourth port;
a first output port for providing a first output signal with the first frequency band; and
a second output port for providing a second output signal with the second frequency band;
wherein the output of the first power amplifier is coupled to the first port of the output coupler, the output of the second power amplifier is coupled to the fourth port of the output coupler, the second port of the output coupler is coupled to the first output port of the power amplifier arrangement via a first transmission line, and the third port of the output coupler is coupled to the second output port of the power amplifier arrangement via a second transmission line;
wherein the output coupler is a dual-band inverse phase coupler such that:
the output signal from the first power amplifier and the output signal from the second power amplifier with the first frequency band are combined in phase at the second port of the output coupler and coupled to the first output port of the power amplifier arrangement via the first transmission line;
the output signal from the first power amplifier and the output signal from the second power amplifier with the second frequency band are combined in phase at the third port of the output coupler and coupled to the second output port of the power amplifier arrangement via the second transmission lines;
the output signal from the first power amplifier and the output signal from the second power amplifier with the first frequency band are cancelled at the third port of the output coupler; and
the output signal from the first power amplifier and the output signal from the second power amplifier with the second frequency band are cancelled at the second port of the output coupler.

11. The dual-band dual-output ports power amplifier arrangement according to claim 10, further comprising an input coupler.

12. The dual-band dual-output ports power amplifier arrangement according to claim 11, wherein the input coupler is a dual-band inverse phase coupler having a first port, a second port, a third port and a fourth port, and wherein:
the first port is for receiving a second input signal with the second frequency band;
the fourth port is for receiving a first input signal with the first frequency band;
the second port is coupled to the input of the first power amplifier; and
the third port is coupled to the input of the second power amplifier.

13. The dual-band dual-output ports power amplifier arrangement according to claim 11, wherein the input coupler is a wideband hybrid coupler having a first port, a second port, a third port and a fourth port and used as an input power divider, and wherein:
the first port is for receiving a first input signal with the first frequency band and a second input signal with the second frequency band;
the second port is coupled to a signal ground via an impedance;
the third port is coupled to the input of the second power amplifier; and
the fourth port is coupled to the input of the first power amplifier.

14. The dual-band dual-output ports power amplifier arrangement according to claim 11, wherein the input coupler is a wideband hybrid coupler having a first port, a second port, a third port and a fourth port and used as an input power divider, and wherein
the first port is coupled to a signal ground via an impedance;
the second port is for receiving a first input signal with the first frequency band and a second input signal with the second frequency band;
the third port is coupled to the input of the second power amplifier; and
the fourth port is coupled to the input of the first power amplifier.

15. The dual-band dual-output ports power amplifier arrangement according to claim 10, further comprising:
a first switch coupled in series with the first output port of the amplifier arrangement; and
a second switch coupled in series with the second output port of the amplifier arrangement.

16. A multiband power amplifier comprising two or more dual-band dual-output ports power amplifier arrangements, wherein each of the two or more dual-band dual-output ports power amplifier arrangements comprises a dual-band dual-output ports power amplifier arrangement according to claim 10.

17. An electronic apparatus comprising one or more power amplifier arrangements, wherein each of the one or more dual-band dual-output ports power amplifier arrangements comprises a dual-band dual-output ports power amplifier arrangement according to claim 10.

18. The electronic apparatus according to claim 17, wherein the electronic apparatus is any one of a transmitter, a transceiver, a wireless communication device, a radio base station, or a network node for a cellular communication system.
